(19) United States
(12) Patent Application Publication
(10) Pub. No.: US 2026/0333558 A1
(43) Pub. Date: Oct. 22, 2026

(54) TARGET SUPPLY DEVICE, EXTREME ULTRAVIOLET LIGHT GENERATION SYSTEM, TARGET SUPPLY METHOD, AND ELECTRONIC DEVICE MANUFACTURING METHOD

(71) Applicant: Gigaphoton Inc., Tochigi (JP)

(72) Inventors: Xianlong NI, Tochigi (JP); Masaki NAKANO, Tochigi (JP); Fumio IWAMOTO, Tochigi (JP)

(73) Assignee: Gigaphoton Inc., Tochigi (JP)

(21) Appl. No.: 19/557,469

(22) Filed: Mar. 5, 2026

(30) Foreign Application Priority Data
Apr. 16, 2025 (JP) 2025-067474

(51) Int. Cl. H05G 2/00; G03F 1/84; G03F 7/00

(52) U.S. Cl. CPC H05G 2/0023; G03F 1/84; G03F 7/70033; H05G 2/0027; H05G 2/003; H05G 2/0082

(57) ABSTRACT

A target supply device includes a first container containing a liquid target substance; a second container allowing the target substance flowed out from the first container to flow therein; a nozzle hole allowing the target substance flowed into the second container to be discharged into a chamber in which extreme ultraviolet light is to be generated; a sealing portion sealing a first space between the first container and the second container; a filter arranged in the first space and allowing the target substance to pass therethrough; and a plate arranged in the first space, located between the filter and a plate-side container, which is one of the first container and the second container, including a first penetration portion allowing the target substance to pass therethrough, and providing gas-permeability between a second space configured by the first penetration portion and a third space outside the plate among the first space.

### CROSS-REFERENCE TO RELATED APPLICATIONS

The present application claims the benefit of Japanese Patent Application No. 2025-067474, filed on Apr. 16, 2025, the entire contents of which are hereby incorporated by reference.

### BACKGROUND

### 1. Technical Field

The present disclosure relates to a target supply device, an extreme ultraviolet light generation system, a target supply method, and an electronic device manufacturing method.

### 2. Related Art

Recently, miniaturization of a transfer pattern in optical lithography of a semiconductor process has been rapidly proceeding along with miniaturization of the semiconductor process. In the next generation, microfabrication at 10 nm or less will be required. Therefore, it is expected to develop a semiconductor exposure apparatus that combines an apparatus for generating extreme ultraviolet (EUV) light having a wavelength of about 13 nm with a reduced projection reflection optical system.

As the EUV light generation apparatus, a laser produced plasma (LPP) type apparatus using plasma generated by irradiating a target substance with laser light has been developed.

### LIST OF DOCUMENTS

### Patent Documents

Patent Document 1: US Patent Application Publication No. 2022/0015218

### SUMMARY

A target supply device according to an aspect of the present disclosure includes a first container configured to contain a liquid target substance; a second container configured to allow the target substance flowed out from the first container to flow therein; a nozzle hole configured to allow the target substance flowed into the second container to be discharged into a chamber in which extreme ultraviolet light is to be generated; a sealing portion configured to seal a first space between the first container and the second container; a filter arranged in the first space and configured to allow the target substance to pass therethrough; and a plate arranged in the first space, located between the filter and a plate-side container, which is one of the first container and the second container, including a first penetration portion configured to allow the target substance to pass therethrough, and providing gas-permeability between a second space configured by the first penetration portion and a third space outside the plate among the first space.

An electronic device manufacturing method according to an aspect of the present disclosure includes generating extreme ultraviolet light using an extreme ultraviolet light generation system, outputting the extreme ultraviolet light to an exposure apparatus, and exposing a photosensitive substrate to the extreme ultraviolet light in the exposure apparatus to manufacture an electronic device. Here, the extreme ultraviolet light generation system includes a target supply device, a chamber connected to the target supply device, a laser device configured to irradiate a target substance with laser light, and an EUV light concentrating mirror configured to concentrate the extreme ultraviolet light generated by irradiating the target substance with the laser light. The target supply device includes a first container configured to contain the liquid target substance; a second container configured to allow the target substance flowed out from the first container to flow therein; a nozzle hole configured to allow the target substance flowed into the second container to be discharged into the chamber in which the extreme ultraviolet light is to be generated; a sealing portion configured to seal a first space between the first container and the second container; a filter arranged in the first space and configured to allow the target substance to pass therethrough; and a plate arranged in the first space, located between the filter and a plate-side container, which is one of the first container and the second container, including a first penetration portion configured to allow the target substance to pass therethrough, and providing gas-permeability between a second space configured by the first penetration portion and a third space outside the plate among the first space.

An electronic device manufacturing method according to an aspect of the present disclosure includes inspecting a defect of a mask by irradiating the mask with extreme ultraviolet light generated by an extreme ultraviolet light generation system, selecting a mask using a result of the inspection, and exposing and transferring a pattern formed on the selected mask onto a photosensitive substrate. Here, the extreme ultraviolet light generation system includes a target supply device, a chamber connected to the target supply device, a laser device configured to irradiate a target substance with laser light, and an EUV light concentrating mirror configured to concentrate the extreme ultraviolet light generated by irradiating the target substance with the laser light. The target supply device includes a first container configured to contain the liquid target substance; a second container configured to allow the target substance flowed out from the first container to flow therein; a nozzle hole configured to allow the target substance flowed into the second container to be discharged into the chamber in which the extreme ultraviolet light is to be generated; a sealing portion configured to seal a first space between the first container and the second container; a filter arranged in the first space and configured to allow the target substance to pass therethrough; and a plate arranged in the first space, located between the filter and a plate-side container, which is one of the first container and the second container, including a first penetration portion configured to allow the target substance to pass therethrough, and providing gas-permeability between a second space configured by the first penetration portion and a third space outside the plate among the first space.

### BRIEF DESCRIPTION OF THE DRAWINGS

Embodiments of the present disclosure will be described below merely as examples with reference to the accompanying drawings.

FIG. 1 shows the configuration of an LPP EUV light generation system according to a comparative example.

FIG. 2 is a partial sectional view showing the configuration of a target supply device according to the comparative example.

FIG. 3 is an enlarged cross-sectional view of a connection part between a first container and a second container in the comparative example.

FIG. 4 is a perspective view of a plate in the comparative example.

FIG. 5 is an enlarged cross-sectional view of the connection part between the first container and the second container in a first embodiment.

FIG. 6 is an enlarged cross-sectional view of the connection part between the first container and the second container in the first embodiment.

FIG. 7 is a perspective view showing an example of a shape of the plate in the first embodiment.

FIG. 8 is a perspective view showing an example of the shape of the plate in the first embodiment.

FIG. 9 is a perspective view showing an example of the shape of the plate in the first embodiment.

FIG. 10 is a perspective view showing an example of the shape of the plate in the first embodiment.

FIG. 11 is a perspective view showing an example of the shape of the plate in the first embodiment.

FIG. 12 is a perspective view showing an example of the shape of the plate in the first embodiment.

FIG. 13 is a perspective view showing an example of the shape of the plate in the first embodiment.

FIG. 14 is a perspective view showing an example of a filter in the first embodiment.

FIG. 15 is an enlarged cross-sectional view of the connection part between the first container and the second container in a second embodiment.

FIG. 16 is an enlarged cross-sectional view of the connection part between the first container and the second container in the second embodiment.

FIG. 17 is an enlarged cross-sectional view of the connection part between the first container and the second container in a third embodiment.

FIG. 18 is an enlarged cross-sectional view of the connection part between the first container and the second container in the third embodiment.

FIG. 19 shows the configuration of an exposure apparatus connected to the EUV light generation system.

FIG. 20 shows the configuration of an inspection apparatus connected to the EUV light generation system.

### DESCRIPTION OF EMBODIMENTS

### CONTENTS

1. Comparative example
   1.1 EUV light generation system 11
      1.1.1 Configuration
      1.1.2 Operation
   1.2 Target supply device 26
      1.2.1 Configuration
      1.2.2 Operation
   1.3 Problem of comparative example
2. Plate 66a with gas-permeability
   2.1 Configuration and operation
   2.2 Shape of plate 66a
   2.3 Example of filter 65
   2.4 Effect
3. Plate 66h configured by porous material
   3.1 Configuration and operation
   3.2 Effect
4. Plate 66a in contact with second container 62
   4.1 Configuration and operation
   4.2 Effect
5. Others
   5.1 Example of EUV light utilization apparatus 6
   5.2 Processor
   5.3 Supplement

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. COMPARATIVE EXAMPLE

### 1.1 EUV Light Generation System 11

### 1.1.1 Configuration

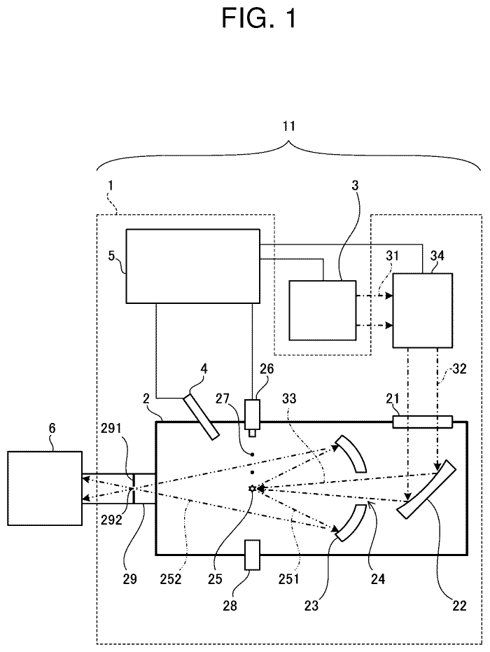

FIG. 1 shows the configuration of an LPP EUV light generation system 11 according to a comparative example. The comparative example of the present disclosure is an example recognized by the applicant as known only by the applicant, and is not a publicly known example admitted by the applicant. An EUV light generation apparatus 1 is used together with a laser device 3. In the present disclosure, a system including the EUV light generation apparatus 1 and the laser device 3 is referred to as the EUV light generation system 11. The EUV light generation apparatus 1 includes a chamber 2 and a target supply device 26. The chamber 2 is a sealable container. The target supply device 26 supplies a target 27 containing a target substance into the chamber 2. The material of the target substance may include tin, terbium, gadolinium, lithium, xenon, or a combination of any two or more thereof.

A through hole is formed in a wall of the chamber 2. The through hole is blocked by a window 21 and laser light 32 output from the laser device 3 is transmitted through the window 21. An EUV light concentrating mirror 23 having a spheroidal reflection surface is arranged in the chamber 2. The EUV light concentrating mirror 23 has first and second focal points. A multilayer reflection film in which molybdenum and silicon are alternately stacked is formed on a surface of the EUV light concentrating mirror 23. The EUV light concentrating mirror 23 is arranged such that the first focal point is located in a plasma generation region 25 and the second focal point is located at an intermediate focal point 292. A through hole 24 is formed at the center of the EUV light concentrating mirror 23, and laser light 33 passes through the through hole 24.

The EUV light generation apparatus 1 includes an EUV light generation processor 5, a target sensor 4, and the like. The configuration of the EUV light generation processor 5 will be described later. The target sensor 4 detects at least one of the presence, trajectory, position, and velocity of the target 27. The target sensor 4 may have an imaging function.

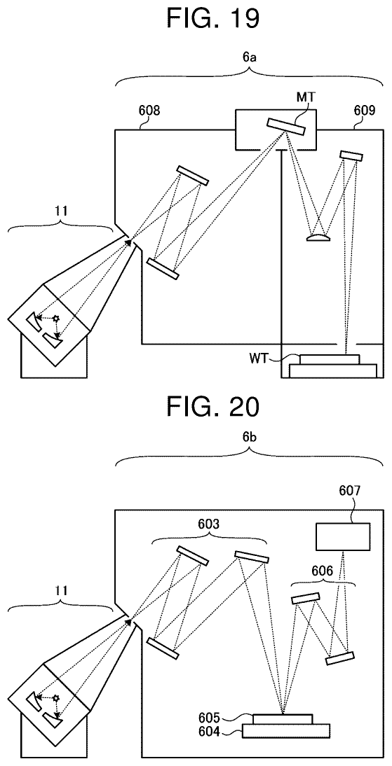

Further, the EUV light generation apparatus 1 includes a connection portion 29 providing communication between the internal space of the chamber 2 and the internal space of an EUV light utilization apparatus 6. The EUV light utilization apparatus 6 may be an exposure apparatus 6a shown in FIG. 19 or an inspection apparatus 6b shown in FIG. 20. A wall 291 in which an aperture is formed is arranged in the connection portion 29. The wall 291 is arranged such that the aperture is located at the second focal point of the EUV light concentrating mirror 23.

Further, the EUV light generation apparatus 1 includes a laser light transmission device 34, a laser light concentrating mirror 22, a target collection unit 28 for collecting the target 27, and the like. The laser light transmission device 34 includes an optical element for defining a transmission state of the laser light 32, and an actuator for adjusting the position, posture, and the like of the optical element.

### 1.1.2 Operation

Operation of the EUV light generation system 11 will be described with reference to FIG. 1. Pulse laser light 31 output from the laser device 3 enters, via the laser light transmission device 34, the chamber 2 through the window 21 as the laser light 32. The laser light 32 travels along a laser light path in the chamber 2, is reflected by the laser light concentrating mirror 22, and is radiated to the target 27 as the laser light 33.

The target supply device 26 outputs the target 27 toward the plasma generation region 25 in the chamber 2. The target 27 is irradiated with the laser light 33. The target 27 irradiated with the laser light 33 is turned into plasma, and radiation light 251 is radiated from the plasma. EUV light contained in the radiation light 251 is reflected by the EUV light concentrating mirror 23 with higher reflectance than light in other wavelength ranges. Reflection light 252 including the EUV light reflected by the EUV light concentrating mirror 23 is concentrated at the intermediate focal point 292 and output to the EUV light utilization apparatus 6. One target 27 may be irradiated with a plurality of pulses included in the laser light 33.

The EUV light generation processor 5 controls the entire EUV light generation system 11. The EUV light generation processor 5 processes a detection result of the target sensor 4. Based on the detection result of the target sensor 4, the EUV light generation processor 5 controls the timing at which the target 27 is output, the output direction of the target 27, and the like. Further, the EUV light generation processor 5 controls oscillation timing of the laser device 3, the travel direction of the laser light 32, the concentration position of the laser light 33, and the like. The above-described various kinds of control are merely examples, and other control may be added as necessary.

### 1.2 Target Supply Device 26

### 1.2.1 Configuration

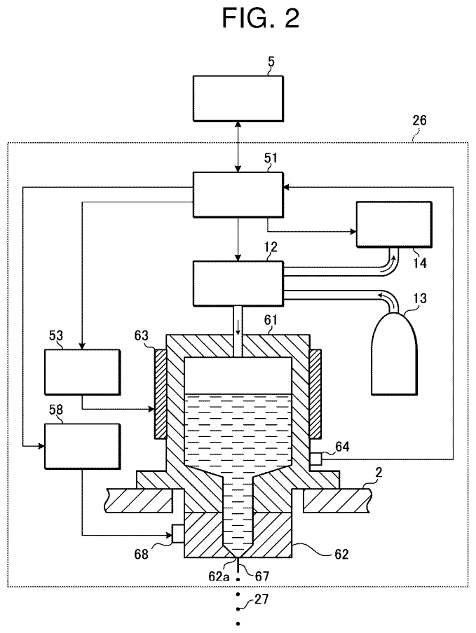

FIG. 2 is a partial sectional view showing the configuration of the target supply device 26 according to the comparative example. The target supply device 26 includes a pressure regulator 12, an inert gas cylinder 13, an exhaust pump 14, a target supply processor 51, a heater power source 53, a piezoelectric element power source 58, a first container 61, and a second container 62. The second container 62 includes a nozzle hole 62a. The configuration of the target supply processor 51 will be described later.

A flange portion of the first container 61 is connected to the chamber 2. The first container 61 stores a liquid target substance containing, for example, tin. A heater 63 is attached to the first container 61 to melt the target substance that is solid at room temperature and to maintain the molten state. The heater power source 53 is connected to the heater 63. A temperature sensor 64 is further attached to the first container 61.

The second container 62 is connected to a lower end of the first container 61, and the nozzle hole 62a is located at a lowermost end of the second container 62. The liquid target substance flowing out from the first container 61 flows into the second container 62 and passes through the inside of the second container 62 toward the nozzle hole 62a. A heater (not shown) may also be attached to the second container 62 to maintain the molten state of the target substance inside the second container 62.

A piezoelectric unit 68 is attached to the second container 62. The piezoelectric unit 68 may include a piezoelectric crystal such as lead zirconate titanate (PZT) and an electrode attached to the piezoelectric crystal. The piezoelectric element power source 58 is connected to the piezoelectric unit 68. When the piezoelectric element power source 58 applies a drive voltage to the piezoelectric crystal included in the piezoelectric unit 68, the second container 62 is vibrated.

The inert gas cylinder 13 and the exhaust pump 14 are connected to the pressure regulator 12 respectively by a separate gas pipe. The pressure regulator 12 is in communication with the inside of the first container 61 by another gas pipe. The inert gas cylinder 13 supplies the inert gas into the first container 61 through the pressure regulator 12. The exhaust pump 14 exhausts the first container 61 through the pressure regulator 12. Alternatively, the exhaust pump 14 may be connected to the pipe between the pressure regulator 12 and the first container 61 without through the pressure regulator 12. In this case, the exhaust pump 14 exhausts the first container 61 without through the pressure regulator 12.

### 1.2.2 Operation

After the exhaust pump 14 exhausts the first container 61 and the second container 62 to less than atmospheric pressure, for example, to a state of approximate vacuum, the first container 61 and the second container 62 are filled with the target substance. The target supply processor 51 controls the value of the current flowing from the heater power source 53 to the heater 63 so that the detection value detected by the temperature sensor 64 is maintained at a target temperature that is equal to or higher than the melting point of the target substance.

The pressure regulator 12 adjusts the pressure of the inert gas supplied from the inert gas cylinder 13 into the first container 61 in response to a control signal output from the target supply processor 51. The inert gas introduced into the first container 61 pressurizes the molten target substance in the first container 61. When the inert gas pressurizes the target substance, a jet 67 of the liquid target substance is discharged from the nozzle hole 62a of the second container 62.

The piezoelectric element power source 58 applies the drive voltage having a waveform corresponding to a control signal output from the target supply processor 51 to the piezoelectric crystal included in the piezoelectric unit 68. As a result, the piezoelectric crystal periodically expands and contracts, and applies vibration to the second container 62. When the vibration applied to the second container 62 satisfies a predetermined condition, a standing wave is generated in the jet 67 of the target substance discharged from the nozzle hole 62a. Due to the surface tension of the target substance, the jet 67 is separated into droplets, and a plurality of targets 27 are generated.

The target 27 output into the chamber 2 is supplied to the plasma generation region 25 in the chamber 2. The EUV light generation processor 5 controls the laser device 3 so that the target 27 output from the target supply device 26 is irradiated with the laser light 33.

### 1.3 Problem of Comparative Example

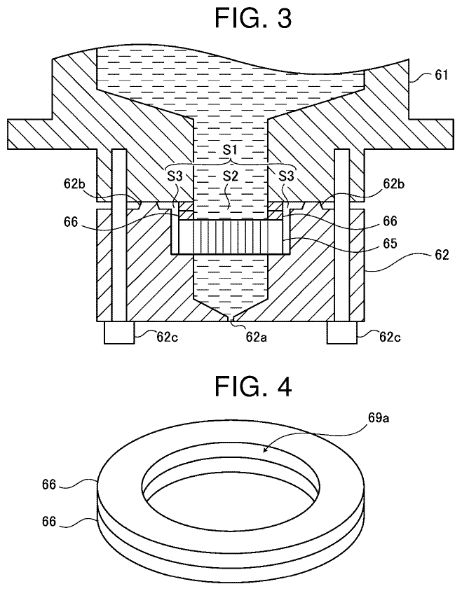

FIG. 3 is an enlarged cross-sectional view of a connection part between the first container 61 and the second container 62 in the comparative example. A recessed portion configuring a first space S1 in which a filter 65 and a plate 66 are arranged is formed on a surface of the second container 62 facing the first container 61. The plate 66 is located between the filter 65 and the first container 61. The first container 61 in the first embodiment corresponds to a plate-side container in the present disclosure. The first space S1 is sealed by a sealing portion 62b. The sealing portion 62b is configured by a ring-shaped protrusion arranged on the surface of the second container 62 facing the first container 61. The second container 62 is fixed while being pressed against the first container 61 by a plurality of bolts 62c.

FIG. 4 is a perspective view of the plate 66 in the comparative example. FIG. 4 shows a state in which two plates 66 are stacked. Each of the plates 66 is a ring-shaped member having a first penetration portion 69a through which the target substance passes. The pressing force of the sealing portion 62b against the first container 61 can be adjusted by increasing or decreasing the number of plates 66 arranged between the filter 65 and the first container 61, or by replacing the plate 66 having a different thickness.

As described above, exhaust by the exhaust pump 14 is performed before the first container 61 and the second container 62 are filled with the target substance, but air containing oxygen gas may remain in a third space S3 (see FIG. 3) outside the plate 66 among the first space S1. Oxygen gas remaining in the third space S3 may gradually leak into a second space S2 configured by the first penetration portion 69a or into the second container 62. The leaked oxygen gas oxidizes a part of the target substance into solid particles. When the solid particles adhere to the nozzle hole 62a, the discharge direction of the target substance is changed, and the relative positional relationship between the trajectory of the target 27 and the light concentration position of the laser light 33 may become unstable. As a result, there is a possibility that the energy stability of the EUV light is deteriorated or the operation rate of the EUV light generation apparatus 11 is deteriorated.

Embodiments described below relate to suppressing generation of an oxide of the target substance by reducing the oxygen gas remaining in the third space S3, and suppressing deterioration in the energy stability of the EUV light and the operation rate of the EUV light generation system 11.

### 2. PLATE 66a WITH GAS-PERMEABILITY

### 2.1 Configuration and Operation

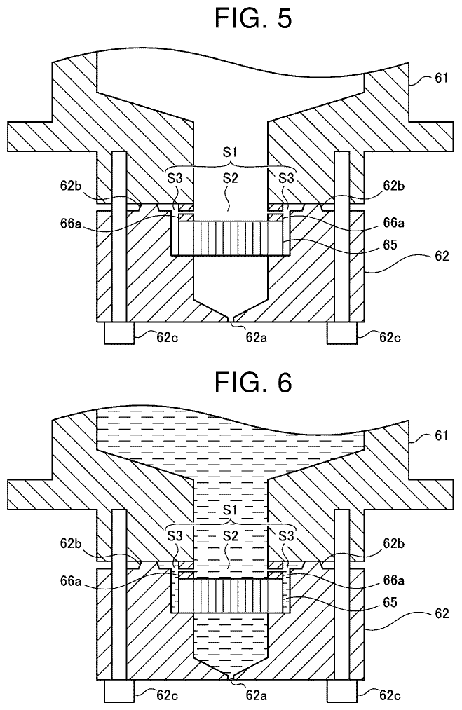

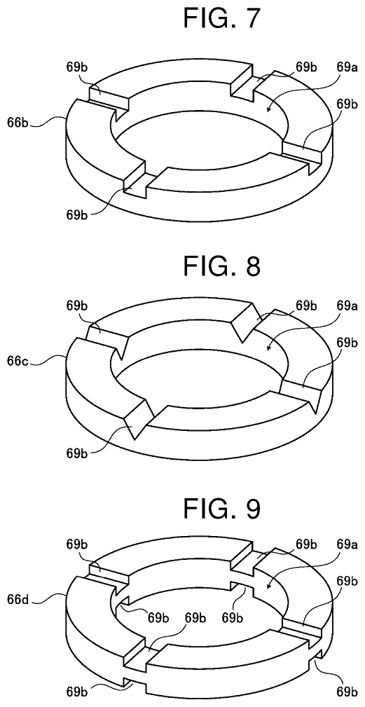

FIGS. 5 and 6 are enlarged cross-sectional views of the connection part between the first container 61 and the second container 62 in a first embodiment. In the first embodiment, the plate 66a is configured to be capable of providing gas-permeability between the second space S2 configured by the first penetration portion 69a and the third space S3 outside the plate 66a among the first space S1. Examples of the shape of the plate 66a will be described later with reference to FIGS. 7 to 13.

As shown in FIG. 5, exhaust by the exhaust pump 14 is performed before the first container 61 and the second container 62 are filled with the target substance. At this time, since air is discharged from the third space S3 to the second space S2 through the gas-permeable plate 66a, the third space S3 can be exhausted.

After the exhaust, as shown in FIG. 6, when the first container 61 and the second container 62 are filled with the target substance, the target substance may also flow from the second space S2 into the third space S3. However, leakage of the target substance from the gap between the first container 61 and the second container 62 is prevented by the sealing portion 62b. The sealing portion 62b preferably has an elastic modulus larger than the elastic modulus of the filter 65 and the elastic modulus of the plate 66a.

The filter 65 is in surface contact with the second container 62 and is pressed against the second container 62 by the plate 66a. Accordingly, the flow of the target substance bypassing the filter 65 from the third space S3 to the second container 62 is suppressed. The flatness and surface roughness of the contact surfaces between the filter 65 and the second container 62 are preferably smaller than those of the contact surface between the plate 66a and the filter 65, and are preferably smaller than those of the contact surfaces between the first container 61 and the plate 66a. The flatness and surface roughness of the contact surfaces between the filter 65 and the second container 62 are 0.01 μm or less and 0.1 μm or less in Ra, respectively.

### 2.2 Shape of Plate 66a

FIGS. 7 to 13 are perspective views each showing an example of the shape of the plate 66a in the first embodiment. The plate 66a is ring-shaped. A plurality of gas-permeable paths are preferably provided between the second space S2 and the third space S3, and the plurality of gas-permeable paths are preferably provided at different positions in the circumferential direction of the plate 66a. In FIGS. 7 to 13, reference numerals 66b to 66g are each used to distinguish a differently shaped plate 66a.

As shown in FIGS. 7 to 9, each of the plates 66b, 66c, 66d may have a first surface in contact with the filter 65 and a second surface in contact with the first container 61, and have grooves 69b providing gas-permeability between the second space S2 and the third space S3 in at least one of the first surface and the second surface. The groove 69b may be a square groove as shown in FIG. 7 or a V groove as shown in FIG. 8. The groove 69b may be on any one of the first and second surfaces, or may be on both the first and second surfaces as shown in FIG. 9.

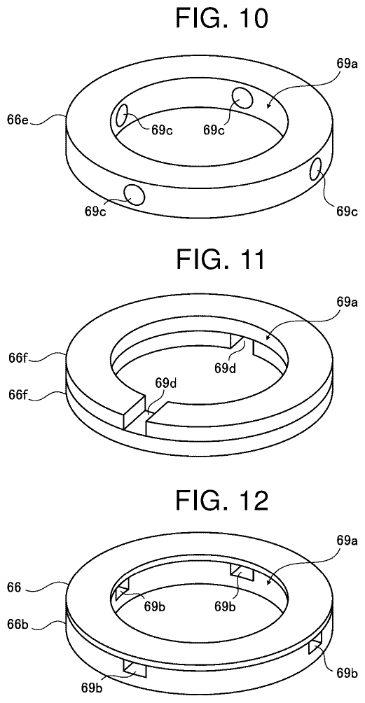

As shown in FIG. 10, the plate 66e may have one or more second penetration portions 69c to provide gas-permeability between the second space S2 and the third space S3.

As shown in FIGS. 11 and 12, a plurality of plates 66f or a plurality of plates 66, 66b may be stacked. FIG. 11 shows an example of arrangement of C-shaped plates 66f each having one cutout 69d such that positions of the cutouts 69d do not overlap each other. FIG. 12 shows a combination of the plate 66 without the groove 69b and the plate 66b with the groove 69b.

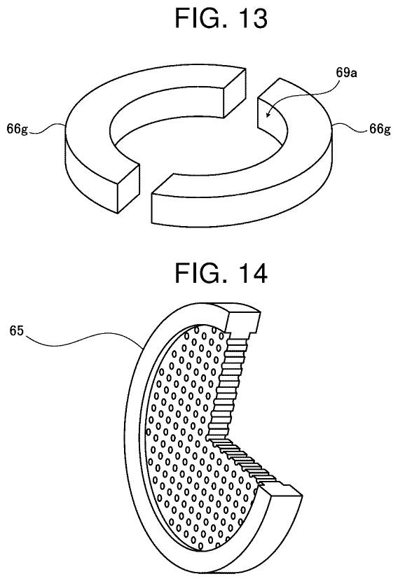

As shown in FIG. 13, a plurality of plates 66g having a semicircular arc shape may be arranged with a gap therebetween, and may have a ring shape as a whole.

### 2.3 Example of Filter 65

FIG. 14 is a perspective view showing an example of the filter 65 in the first embodiment. FIG. 14 shows a state in which a part of the filter 65 is cut out to show the inside thereof. The filter 65 may be a microchannel plate having a number of pores. The cross-sectional area of each of the gas-permeable paths between the second space S2 and the third space S3 formed in the plate 66a is preferably larger than the cross-sectional area of each of the pores.

### 2.4 Effect

According to the first embodiment, the target supply device 26 includes the first container 61, the second container 62, the nozzle hole 62a, the sealing portion 62b, the filter 65, and the plate 66a. The first container 61 stores the liquid target substance. The target substance flowing out of the first container 61 flows into the second container 62. The target substance having flowed into the second container 62 is discharged through the nozzle hole 62a into the chamber 2 in which the EUV light is generated. The sealing portion 62b seals the first space S1 between the first container 61 and the second container 62. The filter 65 is arranged in the first space S1 and allows the target substance to pass therethrough. The plate 66a is arranged in the first space S1, is located between the filter 65 and the plate-side container, which is one of the first container 61 and the second container 62, includes the first penetration portion 69a for allowing the target substance to pass therethrough, and provides gas-permeability between the second space S2 configured by the first penetration portion 69a and the third space S3 outside the plate 66a among the first space S1.

According to the above, owing to that gas-permeability is provided between the second space S2 and the third space S3, the oxygen gas in the third space S3 can also be reduced when the second space S2 is exhausted. Since the oxidized target substance can be prevented from adhering to the nozzle hole 62a, discharge of the target substance can be prevented from becoming unstable.

According to the first embodiment, the sealing portion 62b contains a material having an elastic modulus larger than the elastic modulus of the filter 65 and the elastic modulus of the plate 66a.

According to the above, by adjusting the thickness of the plate 66a, an appropriate pressing force can be applied to the sealing portion 62b, and sealing by the sealing portion 62b can be ensured.

According to the first embodiment, the filter 65 is in surface contact with the other of the first container 61 and the second container 62 other than the plate-side container.

According to the above, it is possible to prevent the target substance from flowing into the second container 62 as bypassing the filter 65.

According to the first embodiment, the flatness and the surface roughness of the contact surfaces between the filter 65 and the second container 62 are smaller than those of the contact surfaces of the plate 66a and the filter 65 and smaller than those of the contact surfaces between the first container 61 and the plate 66a, and are 0.01 μm or less and 0.1 μm or less in Ra, respectively.

According to the above, it is possible to further prevent the target substance from flowing into the second container 62 as bypassing the filter 65.

According to the first embodiment, at least a part of the first space S1 is located in the recessed portion formed on the surface of the second container 62 facing the first container 61.

According to the above, it is possible to facilitate the operation of setting the filter 65 and the plate 66a in the recessed portion of the second container 62 and fixing the second container 62 to the first container 61.

According to the first embodiment, the plate-side container is the first container 61.

According to the above, since the plate 66a is arranged between the filter 65 and the first container 61, it is possible to facilitate the operation of dimension adjustment as adjusting the thickness of the plate 66a without removing the filter 65 after the filter 65 is set in the recessed portion of the second container 62.

According to the first embodiment, each of the plates 66b, 66c, 66d has the first surface in contact with the filter 65 and the second surface in contact with the plate-side container, and has the groove 69b providing gas-permeability between the second space S2 and the third space S3 in at least one of the first surface and the second surface.

According to the above, it is possible to facilitate processing to provide gas-permeability between the filter 65 and the first surface or between the plate-side container and the second surface.

According to the first embodiment, the plate 66e has one or more second penetration portions 69c providing gas-permeability between the second space S2 and the third space S3.

According to the above, gas-permeability between the second space S2 and the third space S3 can be smoothly provided.

According to the first embodiment, the filter 65 is configured by a microchannel plate having a plurality of pores.

According to the above, it is possible to efficiently perform filtering on the target substance.

According to the first embodiment, the cross-sectional area of each of the gas-permeable paths between the second space S2 and the third space S3 formed in the plate 66a is larger than the cross-sectional area of each of the plurality of pores formed in the filter 65.

According to the above, since the cross-sectional area of the gas-permeable path formed in the plate 66a is large, the third space S3 can be efficiently exhausted through the gas-permeable path.

According to the first embodiment, the target supply method includes exhausting the second space S2 and the third space S3 through the first container 61, then filling the first container 61, the second space S2, and the second container 62 with the target substance, and discharging the target substance into the chamber 2 by supplying the gas into the first container 61.

According to the above, the third space S3 can be exhausted through the first container 61 even when the gas-permeability of the filter 65 is insufficient.

In other respects, the first embodiment is similar to the comparative example. Although the nozzle hole 62a is provided at the second container 62, the present disclosure is not limited thereto. A third container to which the target substance flowing out of the second container 62 flows in may be provided, and the nozzle hole may be provided at the third container.

### 3. PLATE 66h CONFIGURED BY POROUS MATERIAL

### 3.1 Configuration and Operation

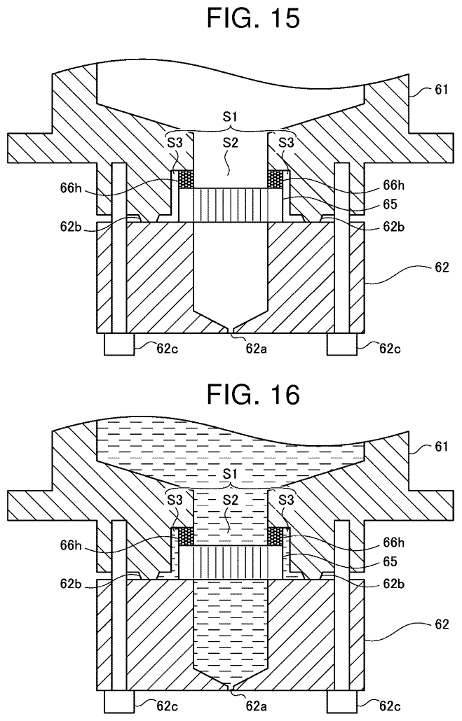

FIGS. 15 and 16 are enlarged cross-sectional views of the connection part between the first container 61 and the second container 62 in a second embodiment. In the second embodiment, a recessed portion configuring the first space S1 in which the filter 65 and a plate 66h are arranged is formed on a surface of the first container 61 facing the second container 62. The plate 66h is located between the filter 65 and the first container 61. The first container 61 in the second embodiment corresponds to a plate-side container in the present disclosure. Further, the sealing portion 62b is configured by a ring-shaped protrusion arranged on the surface of the first container 61 facing the second container 62.

The plate 66h is configured by a permeable porous material, which provides gas-permeability between the second space S2 and the third space S3. Examples of the gas-permeable porous material include the following:
(a) open-cell porous ceramic composed of a material resistant to reaction with liquid tin, such as alumina, silicon carbide, zirconia, silicon nitride, yttria, or aluminum nitride;
(b) porous glass;
(c) open-cell porous metal composed of a material resistant to reaction with tin, such as molybdenum, tungsten, or tantalum, or a sintered body thereof; and
(d) a material obtained by processing any of the materials (a) to (c) into a mesh shape to provide gas-permeability.

As shown in FIG. 15, exhaust by the exhaust pump 14 is performed before the first container 61 and the second container 62 are filled with the target substance. At this time, since air is discharged from the third space S3 to the second space S2 through the gas-permeable plate 66h, the third space S3 can be exhausted.

After the exhaust, as shown in FIG. 16, when the first container 61 and the second container 62 are filled with the target substance, the target substance may also flow from the second space S2 into the third space S3. However, leakage of the target substance from the gap between the first container 61 and the second container 62 is prevented by the sealing portion 62b.

### 3.2 Effect

According to the second embodiment, the plate 66h is configured by a gas-permeable porous material.

According to the above, gas-permeability between the second space S2 and the third space S3 can be provided without processing the groove 69b or the second penetration portion 69c.

In other respects, the second embodiment is similar to the first embodiment. Alternatively, in the second embodiment, a recessed portion configuring the first space S1 may be formed on the surface of the second container 62 facing the first container 61. In the second embodiment, the sealing portion 62b may be arranged on the surface of the second container 62 facing the first container 61. In the first embodiment, a recessed portion configuring the first space S1 may be formed on the surface of the first container 61 facing the second container 62. In the first embodiment, the sealing portion 62b may be arranged on the surface of the first container 61 facing the second container 62.

### 4. PLATE 66a IN CONTACT WITH SECOND CONTAINER 62

### 4.1 Configuration and Operation

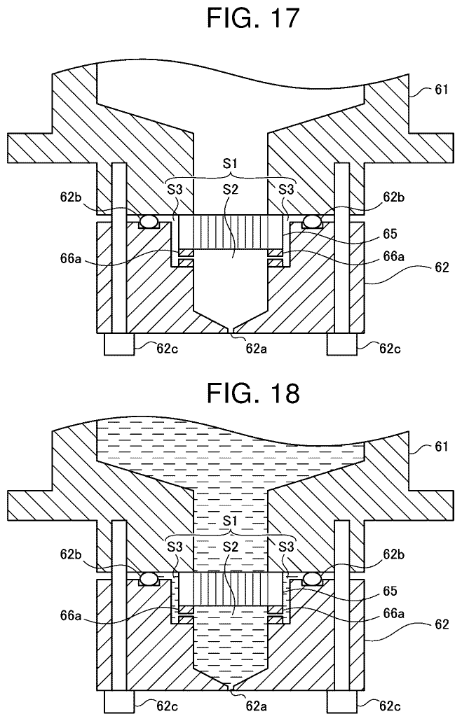

FIGS. 17 and 18 are enlarged cross-sectional views of the connection part between the first container 61 and the second container 62 in a third embodiment. In the third embodiment, a recessed portion configuring the first space S1 in which the filter 65 and the plate 66a are arranged is formed on the surface of the second container 62 facing the first container 61. The plate 66a is located between the filter 65 and the second container 62. The second container 62 in the third embodiment corresponds to the plate-side container in the present disclosure. Further, the sealing portion 62b is configured by an O-ring arranged on the surface of the second container 62 facing the first container 61. Alternatively, the sealing portion 62b may be a ring-shaped metal gasket.

As shown in FIG. 17, exhaust by the exhaust pump 14 is performed before the first container 61 and the second container 62 are filled with the target substance. At this time, it is preferable to also perform exhaust by an exhaust pump (not shown) connected to the chamber 2. Even when the gas-permeability of the filter 65 is insufficient, by exhausting the second container 62 through the chamber 2 and the nozzle hole 62a, air is exhausted from the third space S3 to the second space S2 through the gas-permeable plate 66a, so that the third space S3 can be exhausted.

After the exhaust, as shown in FIG. 18, when the first container 61 and the second container 62 are filled with the target substance, the target substance may also flow from the second space S2 into the third space S3. However, leakage of the target substance from the gap between the first container 61 and the second container 62 is prevented by the sealing portion 62b.

The filter 65 is in surface contact with the first container 61 and is pressed against the first container 61 by the plate 66a. Accordingly, the flow of the target substance bypassing the filter 65 from the first container 61 to the third space S3 is suppressed. The flatness and surface roughness of the contact surfaces between the filter 65 and the first container 61 are preferably smaller than those of the contact surface between the plate 66a and the filter 65, and are preferably smaller than those of the contact surfaces between the second container 62 and the plate 66a. The flatness and surface roughness of the contact surfaces between the filter 65 and the first container 61 are 0.01 μm or less and 0.1 μm or less in Ra, respectively.

### 4.2 Effect

According to the third embodiment, the target supply method includes exhausting the second container 62, the second space S2, and the third space S3 through the chamber 2, then filling the first container 61, the second space S2, and the second container 62 with the target substance, and discharging the target substance into the chamber 2 by supplying the gas into the first container 61.

According to the above, the third space S3 can be exhausted through the chamber 2 even when the gas-permeability of the filter 65 is insufficient.

In other respects, the third embodiment is similar to the first embodiment. Alternatively, in the third embodiment, a recessed portion configuring the first space S1 may be formed on the surface of the first container 61 facing the second container 62, or the plate 66h configured by a gas-permeable porous material may be used instead of the plate 66a. In the third embodiment, the sealing portion 62b may be configured by a ring-shaped protrusion. In the first embodiment or the second embodiment, the sealing portion 62b may be configured by an O-ring or a ring-shaped metal gasket.

### 5. OTHERS

### 5.1 Example of EUV Light Utilization Apparatus 6

FIG. 19 shows the configuration of the exposure apparatus 6a connected to the EUV light generation system 11. The exposure apparatus 6a as the EUV light utilization apparatus 6 (see FIG. 1) includes a mask irradiation unit 608 and a workpiece irradiation unit 609. The mask irradiation unit 608 illuminates, via a reflection optical system, a mask pattern of a mask table MT with the EUV light incident from the EUV light generation system 11. The workpiece irradiation unit 609 images the EUV light reflected by the mask table MT onto a workpiece (not shown) arranged on a workpiece table WT via a reflection optical system. The workpiece is a photosensitive substrate such as a semiconductor wafer on which photoresist is applied. The exposure apparatus 6a synchronously translates the mask table MT and the workpiece table WT to expose the workpiece to the EUV light reflecting the mask pattern. Through the exposure process as described above, a device pattern is transferred onto the semiconductor wafer, thereby an electronic device can be manufactured.

FIG. 20 shows the configuration of the inspection apparatus 6b connected to the EUV light generation system 11. The inspection apparatus 6b as the EUV light utilization apparatus 6 (see FIG. 1) includes an illumination optical system 603 and a detection optical system 606. The illumination optical system 603 reflects the EUV light incident from the EUV light generation system 11 to illuminate a mask 605 placed on a mask stage 604. Here, the mask 605 conceptually includes a mask blanks before a pattern is formed. The detection optical system 606 reflects the EUV light from the illuminated mask 605 and forms an image on a light receiving surface of a detector 607. The detector 607 having received the EUV light obtains the image of the mask 605. The detector 607 is, for example, a time delay integration (TDI) camera. Inspection for a defect of the mask 605 is performed based on the image of the mask 605 obtained by the above-described steps, and a mask suitable for manufacturing an electronic device is selected using the inspection result. Then, the electronic device can be manufactured by exposing and transferring the pattern formed on the selected mask onto the photosensitive substrate using the exposure apparatus 6a.

### 5.2 Processor

The processor such as the EUV light generation processor 5 and the target supply processor 51 may be physically configured as hardware to execute various processes included in the present disclosure. For example, the processor may be a computer including a memory that stores a control program defining the various processes and a processing device that executes the control program. The control program may be stored in one memory, or may be stored separately in a plurality of memories at physically separate locations, and the various processes included may be defined by the control program as an aggregation thereof. The processing device may be a general-purpose processing device such as a CPU or a special-purpose processing device such as a GPU.

Alternatively, the processor may be programmed as software to execute the various processes included in the present disclosure. For example, the processor may be implemented in a dedicated device such as an ASIC or a programmable device such as an FPGA.

The various processes included in the present disclosure may be executed by one computer, one dedicated device, or one programmable device, or may be executed by cooperation of a plurality of computers, a plurality of dedicated devices, or a plurality of programmable devices at physically separate locations. The various processes may be executed by a combination including at least any two of: one or more computers, one or more dedicated devices, and one or more programmable devices.

### 5.3 Supplement

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, “at least one of A, B, and C” should be interpreted to mean any of A, B, C, A+B, A+C, B+C, and A+B+C as well as to include combinations of the any thereof and any other than A, B, and C.

What is claimed is:

1. A target supply device comprising:
a first container configured to contain a liquid target substance;
a second container configured to allow the target substance flowed out from the first container to flow therein;
a nozzle hole configured to allow the target substance flowed into the second container to be discharged into a chamber in which extreme ultraviolet light is to be generated;
a sealing portion configured to seal a first space between the first container and the second container;
a filter arranged in the first space and configured to allow the target substance to pass therethrough; and
a plate arranged in the first space, located between the filter and a plate-side container, which is one of the first container and the second container, including a first penetration portion configured to allow the target substance to pass therethrough, and providing gas-permeability between a second space configured by the first penetration portion and a third space outside the plate among the first space.

2. The target supply device according to claim 1,
wherein the sealing portion contains a material having an elastic modulus larger than an elastic modulus of the filter and an elastic modulus of the plate.

3. The target supply device according to claim 1,
wherein the filter is in surface contact with the other of the first container and the second container other than the plate-side container.

4. The target supply device according to claim 3,
wherein flatness and surface roughness of contact surfaces between the filter and the other container are smaller than those of contact surfaces between the plate and the filter.

5. The target supply device according to claim 3,
wherein flatness and surface roughness of contact surfaces between the filter and the other container are smaller than those of contact surfaces between the plate-side container and the plate.

6. The target supply device according to claim 3,
wherein flatness and surface roughness of contact surfaces between the filter and the other container are 0.01 μm or less and 0.1 μm or less in Ra, respectively.

7. The target supply device according to claim 1,
wherein at least a part of the first space is located in a recessed portion formed on a surface of the second container facing the first container.

8. The target supply device according to claim 7,
wherein the plate-side container is the first container.

9. The target supply device according to claim 1,
wherein the plate is ring-shaped.

10. The target supply device according to claim 1,
wherein the plate has a first surface in contact with the filter and a second surface in contact with the plate-side container, and has a groove providing gas-permeability between the second space and the third space in at least one of the first surface and the second surface.

11. The target supply device according to claim 1,
wherein the plate has a second penetration portion that provides gas-permeability between the second space and the third space.

12. The target supply device according to claim 1,
wherein the plate has a plurality of second penetration portions that provide gas-permeability between the second space and the third space.

13. The target supply device according to claim 1,
wherein the plate is configured by a gas-permeable porous material.

14. The target supply device according to claim 1,
wherein the filter is configured by a microchannel plate having a plurality of pores.

15. The target supply device according to claim 14,
wherein cross-sectional area of each of gas-permeable paths between the second space and the third space formed in the plate is larger than cross-sectional area of each of the plurality of pores.

16. An extreme ultraviolet light generation system, comprising:
the target supply device according to claim 1;
the chamber connected to the target supply device;
a laser device configured to irradiate the target substance discharged into the chamber with laser light; and
an EUV light concentrating mirror configured to concentrate the extreme ultraviolet light generated by irradiating the target substance with the laser light.

17. A target supply method comprising:
in the extreme ultraviolet light generation system according to claim 16,
exhausting the second space and the third space through the first container;
then, filling the first container, the second space, and the second container with the target substance; and
discharging the target substance into the chamber by supplying a gas into the first container.

18. A target supply method comprising:
in the extreme ultraviolet light generation system according to claim 16,
exhausting the second container, the second space, and the third space through the chamber;
then, filling the first container, the second space, and the second container with the target substance; and
discharging the target substance into the chamber by supplying a gas into the first container.

19. An electronic device manufacturing method, comprising:
generating extreme ultraviolet light using an extreme ultraviolet light generation system;
outputting the extreme ultraviolet light to an exposure apparatus; and
exposing a photosensitive substrate to the extreme ultraviolet light in the exposure apparatus to manufacture an electronic device,
the extreme ultraviolet light generation system including:
a target supply device;
a chamber connected to the target supply device;
a laser device configured to irradiate a target substance with laser light; and
an EUV light concentrating mirror configured to concentrate the extreme ultraviolet light generated by irradiating the target substance with the laser light, and
the target supply device including:
a first container configured to contain the liquid target substance;
a second container configured to allow the target substance flowed out from the first container to flow therein;
a nozzle hole configured to allow the target substance flowed into the second container to be discharged into the chamber in which the extreme ultraviolet light is to be generated;
a sealing portion configured to seal a first space between the first container and the second container;
a filter arranged in the first space and configured to allow the target substance to pass therethrough; and
a plate arranged in the first space, located between the filter and a plate-side container, which is one of the first container and the second container, including a first penetration portion configured to allow the target substance to pass therethrough, and providing gas-permeability between a second space configured by the first penetration portion and a third space outside the plate among the first space.

20. An electronic device manufacturing method, comprising:
inspecting a defect of a mask by irradiating the mask with extreme ultraviolet light generated by an extreme ultraviolet light generation system;
selecting a mask using a result of the inspection; and
exposing and transferring a pattern formed on the selected mask onto a photosensitive substrate,
the extreme ultraviolet light generation system including:
a target supply device;
a chamber connected to the target supply device;
a laser device configured to irradiate a target substance with laser light; and
an EUV light concentrating mirror configured to concentrate the extreme ultraviolet light generated by irradiating the target substance with the laser light, and
the target supply device including:
a first container configured to contain the liquid target substance;
a second container configured to allow the target substance flowed out from the first container to flow therein;
a nozzle hole configured to allow the target substance flowed into the second container to be discharged into the chamber in which the extreme ultraviolet light is to be generated;
a sealing portion configured to seal a first space between the first container and the second container;
a filter arranged in the first space and configured to allow the target substance to pass therethrough; and
a plate arranged in the first space, located between the filter and a plate-side container, which is one of the first container and the second container, including a first penetration portion configured to allow the target substance to pass therethrough, and providing gas-permeability between a second space configured by the first penetration portion and a third space outside the plate among the first space.
